(19) United States
(12) Patent Application Publication
(10) Pub. No.: US 2021/0384102 A1
(43) Pub. Date: Dec. 9, 2021

(54) LOW NOISE AMPLIFIERS ON SOI WITH ON-DIE COOLING STRUCTURES

(71) Applicant: Mobix Labs, Inc., Irvine, CA (US)

(72) Inventors: Oleksandr Gorbachov, Irvine, CA (US); Lisette L. Zhang, Irvine, CA (US)

(21) Appl. No.: 17/336,850

(22) Filed: Jun. 2, 2021

Related U.S. Application Data
(60) Provisional application No. 63/034,614, filed on Jun. 4, 2020.

(51) Int. Cl. H01L 23/38; H01L 23/427; H03F 3/195

(52) U.S. Cl. CPC H01L 23/38; H03F 2200/294; H03F 3/195; H01L 23/427

(57) ABSTRACT

A cooling structure for a silicon-on-insulator (SOI) metal-oxide-semiconductor field-effect transistor (MOSFET) includes a plurality of semiconductor strips separated from each other by isolation trenches, each of the semiconductor strips extending away from a transistor P-well disposed on top of a buried oxide (BOX) layer formed in a semiconductor substrate and having first and second ends, the second end being farther than the first end from the transistor P-well. Applying a voltage to the plurality of semiconductor strips may generate, in at least one of the strips, a first area having a reduced temperature closer to the first end than to the second end of the strip and a second area having an increased temperature closer to the second end than to the first end of the strip. The first and second areas may be generated by the Peltier effect.

### CROSS-REFERENCE TO RELATED APPLICATIONS

This application relates to and claims the benefit of U.S. Provisional Application No. 63/034,614, filed Jun. 4, 2020 and entitled “LOW NOISE AMPLIFIERS ON SOI WITH ON-DIE COOLING STRUCTURES,” the disclosure of which is wholly incorporated by reference in its entirety herein.

### STATEMENT RE: FEDERALLY SPONSORED RESEARCH/DEVELOPMENT

Not Applicable

### BACKGROUND

### 1. Technical Field

The present disclosure relates generally to semiconductor devices such as radio frequency (RF) low noise amplifiers (LNA) and, more particularly, to cooling structures for silicon-on-insulator (SOI) designs.

### 2. Related Art

Silicon-on-insulator (SOI) designs are utilized extensively for semiconductor devices used in radio frequency (RF) communications, such as RF low noise amplifiers (LNAs), antenna switches, and recently, in millimeter-wave (mmWave) phased array beamformers including power amplifiers (PAs). While SOI designs have been found to achieve good performance at a variety of frequencies, the placement of the buried oxide (BOX) dielectric layer between the active transistor areas and the silicon substrate makes heat dissipation more difficult than in the case of bulk silicon devices. For some applications, such as in low power portable devices (e.g. mobile phones), heat dissipation is not a big concern as heat can be adequately dissipated through multiple metal layers to the ambient environment. However, in the case of highly linear LNA devices with large blocking capabilities such as those typically used in base stations, the DC current through the device may be high. With inefficient heat dissipation, this high DC current may result in a high temperature of the LNA active area, increasing the noise figure of the device. The heat dissipation issue is particularly problematic in arrays of linear PAs in 5G or satellite communications, where bulky heat sinks are often required for large phased-array beam-formers to achieve certain error vector magnitude (EVM) and effective isotropic radiated power (EIRP) in transmit mode.

### BRIEF SUMMARY

The present disclosure contemplates various devices and methods for overcoming the above drawbacks associated with the related art. One aspect of the embodiments of the present disclosure is a cooling structure for a silicon-on-insulator (SOI) semiconductor device. The cooling structure may comprise a semiconductor substrate, a buried oxide (BOX) layer formed in the semiconductor substrate, a device P-well disposed on top of the BOX layer, and a plurality of semiconductor strips separated from each other by isolation trenches and each defined by first and second ends. Each of the semiconductor strips may extend away from the device P-well with the second end being farther than the first end from the device P-well. The cooling structure may comprise a first metal interconnect electrically connecting a first set of the semiconductor strips at respective first connection points thereof, the first connection point of each of the strips of the first set being closer to the first end than to the second end. The cooling structure may comprise a second metal interconnect electrically connecting a second set of the semiconductor strips at respective second connection points thereof, the second connection point of each of the strips of the second set being closer to the second end than to the first end. The second set may have at least one of the semiconductor strips in common with the first set, and the first and second metal interconnects may be electrically connected to each other by the at least one of the semiconductor strips.

Each of the semiconductor strips may comprise an N-well. Each of the semiconductor strips may comprise an N+ doped layer disposed inside the N-well. Each of the N-wells may individually abut the device P-well. The N-wells may be connected to each other at the first ends of the strips to form a shared N-well that abuts the device P-well. The cooling structure may comprise a plurality of N-doped polysilicon strips, each of the N-doped polysilicon strips being disposed on top of a corresponding one of the semiconductor strips and separated therefrom by a dielectric or each of the N-doped polysilicon strips being disposed on top of a corresponding one of the isolation trenches and separated therefrom by a dielectric. For each of the at least one of the semiconductor strips that electrically connects the first and second interconnects, a corresponding one of the N-doped polysilicon strips may be electrically connected to the first and second metal interconnects in parallel with the semiconductor strip. The cooling structure may comprise a current source or voltage source configured to generate a DC current that flows from the second metal interconnect through the plurality of semiconductor strips to the first metal interconnect, the DC current flowing through the plurality of semiconductor strips in parallel.

Each of the semiconductor strips may comprise a P-well. The cooling structure may comprise an N-well formed between the device P-well and the P-wells of each of the semiconductor strips. Each of the semiconductor strips may comprise a P+ doped layer disposed inside the P-well. The cooling structure may further comprise a plurality of P-doped polysilicon strips, each of the P-doped polysilicon strips being disposed on top of a corresponding one of the semiconductor strips or isolation trenches and separated therefrom by a dielectric. For each of the at least one of the semiconductor strips that electrically connects the first and second interconnects, a corresponding one of the P-doped polysilicon strips may be electrically connected to the first and second metal interconnects in parallel with the semiconductor strip. The cooling structure may further comprise one or more contacts electrically connecting the P-well of at least one of the semiconductor strips to the N-well. The cooling structure may further comprise a current source or voltage source configured to generate a DC current that flows from the first metal interconnect through the plurality of semiconductor strips to the second metal interconnect, the DC current flowing through the plurality of semiconductor strips in parallel.

The plurality of semiconductor strips may comprise two or more first semiconductor strips arranged alternatingly with two or more second semiconductor strips, each of the first semiconductor strips comprising an N-well and each of the second semiconductor strips comprising a P-well. The cooling structure may comprise a first metal terminal connected to one of the first semiconductor strips at a terminal point thereof, the terminal point being closer to the second end than to the first end of the strip, and a second metal terminal connected to one of the second semiconductor strips at a terminal point thereof, the terminal point being closer to the second end than to the first end of the strip. Each of the first semiconductor strips may comprise an N+ doped layer disposed inside the N-well. Each of the second semiconductor strips may comprise a P+ doped layer disposed inside the P-well. The cooling structure may comprise a current source or voltage source configured to generate a DC current that flows from the first metal terminal through the plurality of semiconductor strips and through the first and second metal interconnects to the second metal terminal. Within each pair of a first semiconductor strip and a second semiconductor strip, the DC current may flow through the first and second semiconductor strips in series. The first and second metal interconnects may be arranged such that the DC current flows through different pairs of a first semiconductor strip and a second semiconductor strip in parallel. The cooling structure may comprise a plurality of N-doped polysilicon strips, each of the N-doped polysilicon strips being disposed on top of a corresponding one of the first semiconductor strips or isolation trenches and separated therefrom by a dielectric. For each of the first semiconductor strips that electrically connects the first and second interconnects, a corresponding one of the N-doped polysilicon strips may be electrically connected to the first and second metal interconnects in parallel with the first semiconductor strip. The cooling structure may comprise a plurality of P-doped polysilicon strips, each of the P-doped polysilicon strips being placed on top of a corresponding one of the second semiconductor strips or isolation trenches and separated therefrom by a dielectric. For each of the second semiconductor strips that electrically connects the first and second interconnects, a corresponding one of the P-doped polysilicon strips may be electrically connected to the first and second metal interconnects in parallel with the second semiconductor strip.

Another aspect of the embodiments of the present disclosure is a silicon-on-insulator (SOI) die. The SOI die may comprise a semiconductor substrate, a buried oxide (BOX) layer formed in the semiconductor substrate, a P-well disposed on top of the buried oxide (BOX) layer, an N-type metal-oxide-semiconductor (NMOS) transistor inside the P-well, and a plurality of semiconductor strips extending away from the P-well and separated from each other by isolation trenches, each of the semiconductor strips having first and second ends, the second end being farther than the first end from the P-well. The SOI die may comprise a first metal interconnect electrically connecting a first set of the semiconductor strips at respective first connection points thereof, the first connection point of each of the strips of the first set being closer to the first end than to the second end, and a second metal interconnect electrically connecting a second set of the semiconductor strips at respective second connection points thereof, the second connection point of each of the strips of the second set being closer to the second end than to the first end. The second set may have at least one of the semiconductor strips in common with the first set, and the first and second metal interconnects may be electrically connected to each other by the at least one of the semiconductor strips.

Another aspect of the embodiments of the present disclosure is a radio frequency (RF) low noise amplifier comprising the SOI die.

Another aspect of the embodiments of the present disclosure is a base station comprising the RF low noise amplifier.

Another aspect of the embodiments of the present disclosure is a method of cooling a silicon-on-insulator (SOI) metal-oxide-semiconductor field-effect transistor (MOSFET). The method may comprise providing a plurality of semiconductor strips separated from each other by isolation trenches, each of the semiconductor strips extending away from a P-well disposed on top of a buried oxide (BOX) layer formed in a semiconductor substrate and having first and second ends, the second end being farther than the first end from the P-well. The method may comprise applying a voltage to the plurality of semiconductor strips so as to generate, in at least one of the strips, a first area having a reduced temperature closer to the first end than to the second end of the strip and a second area having an increased temperature closer to the second end than to the first end of the strip, the first and second areas being generated by the Peltier effect.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a top view of a silicon-on-insulator (SOI) die including a cooling structure according to an embodiment of the present disclosure;

FIG. 2 is a cross-sectional view taken along the line 2-2 in FIG. 1;

FIG. 3 is cross-sectional view taken along the line 3-3 in FIG. 1;

FIG. 4 is a top view of another SOI die including a cooling structure according to an embodiment of the present disclosure;

FIG. 5 is a cross-sectional view taken along the line 5-5 in FIG. 4;

FIG. 6 is a top view of another SOI die including a cooling structure according to an embodiment of the present disclosure;

FIG. 7 is a cross-sectional view taken along the line 7-7 in FIG. 6;

FIG. 8 is a cross-sectional view taken along the line 8-8 in FIG. 6;

FIG. 9 is a top view of another SOI die including a cooling structure according to an embodiment of the present disclosure;

FIG. 10 is a cross-sectional view taken along the line 10-10 in FIG. 9;

FIG. 11 is a top view of another SOI die including a cooling structure according to an embodiment of the present disclosure;

FIG. 12 is a cross-sectional view taken along the line 12-12 in FIG. 11;

FIG. 13 is a cross-sectional view taken along the line 13-13 in FIG. 11;

FIG. 14 is a top view of another SOI die including a cooling structure according to an embodiment of the present disclosure;

FIG. 15 is a cross-sectional view taken along the line 15-15 in FIG. 14;

FIG. 16 is a cross-sectional view taken along the line 16-16 in FIG. 14;

FIG. 17 is a top view of another SOI die including a cooling structure according to an embodiment of the present disclosure;

FIG. 18 is a cross-sectional view taken along the line 18-18 in FIG. 17;

FIG. 19 is a top view of another SOI die including a cooling structure according to an embodiment of the present disclosure;

FIG. 20 is a cross-sectional view taken along the line 20-20 in FIG. 19;

FIG. 21 is a cross-sectional view taken along the line 21-21 in FIG. 19;

FIG. 22 is a top view of another SOI die including a cooling structure according to an embodiment of the present disclosure;

FIG. 23 is a cross-sectional view taken along the line 23-23 in FIG. 22;

FIG. 24 is a cross-sectional view taken along the line 24-24 in FIG. 22; and

FIG. 25 is a cross-sectional view of a modified version of the SOI die of FIG. 22.

### DETAILED DESCRIPTION

The present disclosure encompasses various embodiments of cooling structures and methods for silicon-on-insulator (SOI) semiconductor devices such as metal-oxide-semiconductor field-effect transistors (MOSFETs). The detailed description set forth below in connection with the appended drawings is intended as a description of several currently contemplated embodiments and is not intended to represent the only form in which the disclosed invention may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

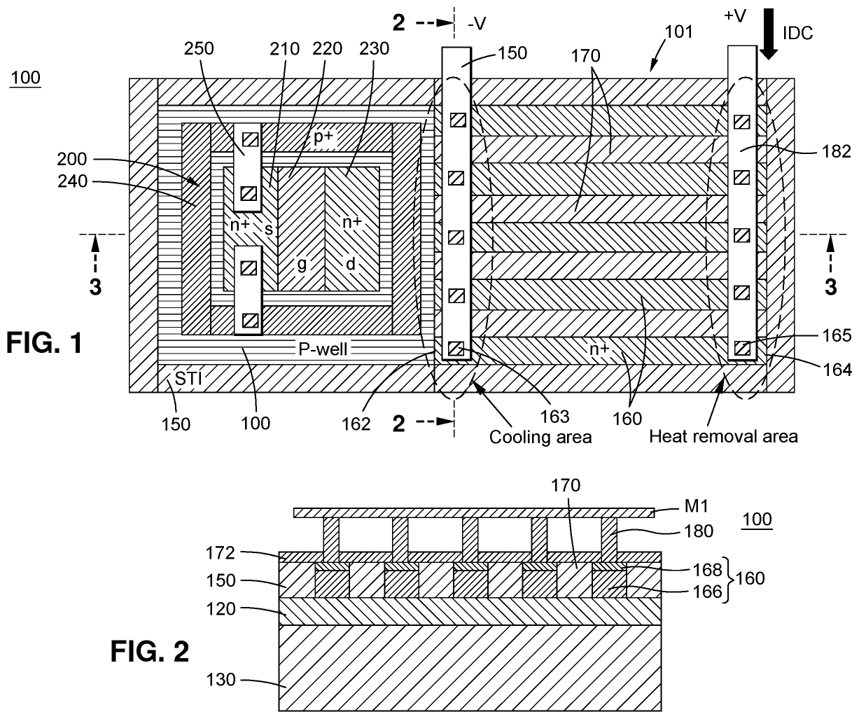

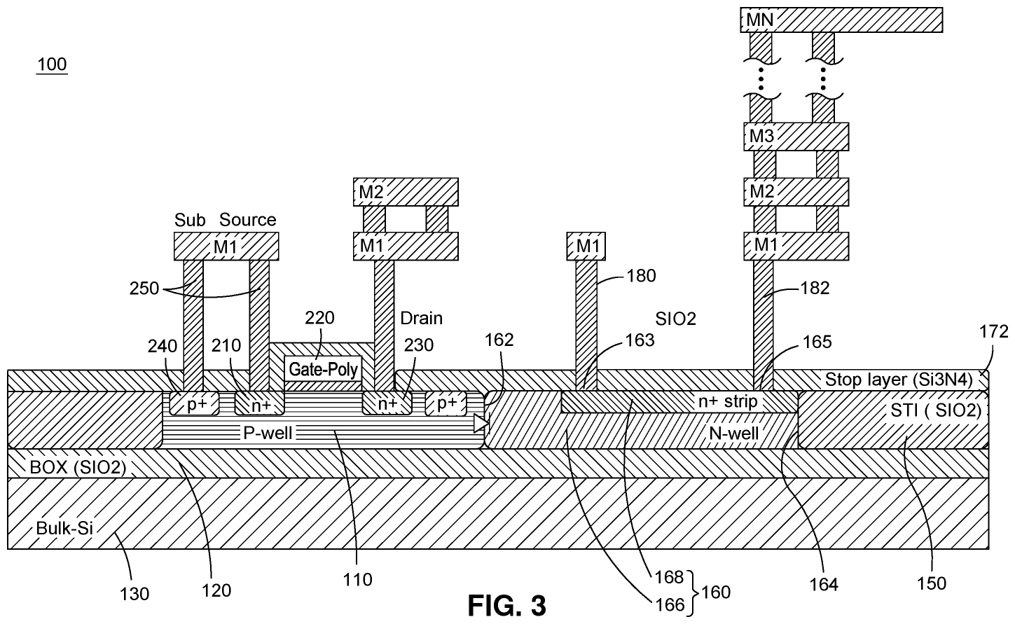

FIG. 1 is a top view of a silicon-on-insulator (SOI) die 100 including a cooling structure 101 according to an embodiment of the present disclosure. FIGS. 2 and 3 are cross-sectional views taken along the lines 2-2 and 3-3 in FIG. 1, respectively. The SOI die 100 may include a semiconductor device such as an N-type metal-oxide-semiconductor (NMOS) transistor 200 of a radio frequency (RF) low noise amplifier (LNA), as may be implemented in a base station of a cellular network (e.g. a 5G network), for example. The NMOS transistor 200, including source 210, gate 220, and drain 230, may be placed inside a P-well 110 that is disposed on top of a buried oxide (BOX) layer 120 serving as the insulator of the SOI die 100. The BOX layer 120 may be made of silicon dioxide (SiO₂), for example, and may be formed in a semiconductor substrate 130 that may be made of bulk semiconductor material such as silicon. As shown, a P+ diffusion strip 240 may be formed around the transistor 200 and connected to the source 210 thereof by a metal contact 250 (see FIG. 1, with alternate arrangement in FIG. 3), the source 210 being connected to the semiconductor substrate 130 and typically tied to ground for LNA applications.

The P-well 110 that is disposed on top of the BOX layer 120 may be surrounded by an isolation trench 150, which may be formed in a shallow trench isolation (STI) layer made of silicon dioxide (SiO₂), for example. As a result of the BOX layer 120 and the isolation trench 150, there may be very low heat dissipation through the semiconductor substrate 130. However, unlike conventional SOI designs, which rely on multiple metal layers with contacts between them for heat dissipation, the SOI die 100 includes the cooling structure 101, shown generally extending to the right-hand side of the NMOS transistor 200 in FIG. 1, which allows for on-die cooling of the NMOS transistor 200 by application of the Peltier effect. In the case of an NMOS transistor 200 of an RF LNA, for example, the decrease in operating temperature inside the active area may beneficially reduce the noise figure. It should be noted that the cooling structure 101 described herein is shown on a single side of the NMOS transistor 200 for ease of illustration, but that the same cooling structure 101 may be duplicated and expanded to surround one or more NMOS transistors 200 on all sides, such as in the case of a multi-finger NMOS die.

As shown in FIGS. 1-3, the cooling structure 101 of the SOI die 100 may be defined by a plurality of semiconductor strips 160 extending away from the P-well 110 containing the NMOS transistor 200 (also referred to as the device P-well 110). The semiconductor strips 160 may be separated by isolation trenches 170, which may be formed in the same STI layer as the isolation trench 150, for example. Each of the semiconductor strips 160 may be defined by a first end 162 and a second end 164, the second end 164 being farther than the first end 162 from the P-well 110. When a voltage is applied to the plurality of semiconductor strips 160 as described herein, a resulting DC current in the strips 160 may generate, by the Peltier effect, a first area (“Cooling area” in FIG. 1) having a reduced temperature and a second area (“Heat removal area”) having an increased temperature in at least one of the strips 160. As shown in FIG. 1, the first area may be closer to the first end 162 than to the second end 164 of the at least one of the strips 160, namely closer to the end that is nearer the P-well 110 and NMOS transistor 200 contained therein, while the second area may be closer to the second end 164 than to the first end 162. In this way, the NMOS transistor 200 may be cooled by the Peltier effect while heat is removed toward the far end 164 of the strip(s) 260.

In the example of FIGS. 1-3, each of the semiconductor strips comprises an N-well 166 (see FIGS. 2 and 3). As shown in FIG. 3, each of the N-wells 166 may abut the device P-well 110. The resulting P-N junction contact between the device P-well 110 and the N-wells 166 may function as a diode as schematically depicted in FIG. 3, thus preventing the DC current in the strips 160 from flowing to the NMOS transistor 200. Each semiconductor strip may further comprise an N+ doped layer 168 disposed inside the N-well 166. A high charge carrier concentration diffusion such as the N+ doped layer 168 may result in higher electrical conductivity and increased heat transfer for the same DC current flowing in the strips 160. However, it is contemplated that the N+ doped layer 168 may be omitted in some cases.

In order to generate a DC current in the plurality of semiconductor strips 160 to produce the cooling effect, a voltage may be applied via one or more metal terminals and/or interconnects between the strips 160. For example, as shown in FIG. 1, first and second metal interconnects 180, 182 are provided connecting the strips 160, with each metal interconnect 180, 182 also serving as a terminal for applying voltage as represented by +V and −V. The first metal interconnect 180 may electrically connect a first set of the semiconductor strips 160 at respective first connection points 163 thereof, the first connection point 163 of each of the strips 160 of the first set being closer to the first end 162 than to the second end 164. The second metal interconnect 182 may electrically connect a second set of the semiconductor strips 160 (the same set as the first set in the example of FIG. 1) at respective second connection points 165 thereof, the second connection point 165 of each of the strips 160 of the second set being closer to the second end 164 than to the first end 162. The first and second metal interconnects 180, 182 may connect to the semiconductor strips 160 through a stop layer 172, which may be made of silicon nitride (Si₃N₄), for example.

In general, the second set of semiconductor strips 160 (i.e. the set connected by the second metal interconnect 182) may have at least one of the semiconductor strips 160 in common with the first set (i.e. the set connected by the first metal interconnect 180). In this way, the first and second metal interconnects 180, 182 may be electrically connected to each other by the at least one of the semiconductor strips 160 in common between the two sets. As noted above, all five of the semiconductor strips 160 in the example of FIG. 1 are in common to both sets, such that each of the strips 160 individually serves as a current pathway between the first and second metal interconnects 180, 182. The voltage applied to the strips 160, and consequently the DC current IDC, may be produced by a current source or voltage source (represented by +V and −V in FIG. 1) that is configured to generate a DC current. In the example of FIG. 1, where the strips 160 are N-type (each comprising an N-well 166 and optional N+ strip 168), the DC current IDC is generated so as to flow from the second metal interconnect 182 (i.e. the one that is farther from the device 200) through the plurality of semiconductor strips 160 to the first metal interconnect 180 (i.e. the one that is closer to the device 200), with the DC current IDC flowing through the plurality of semiconductor strips 160 in parallel. As a result, the N-metal junction where current flows from N-type semiconductor to metal at the first connection points 163 (where the first metal interconnect 180 meets each strip 160) becomes cooler by the Peltier effect, while the metal-N junction where current flows from metal to N-type semiconductor at the second connection points 165 (where the second metal interconnect 182 meets each strip 160) becomes warmer by the Peltier effect. On the heat removal side, multiple metal layers M1, M2, M3, . . . MN may be provided having different sizes and shapes.

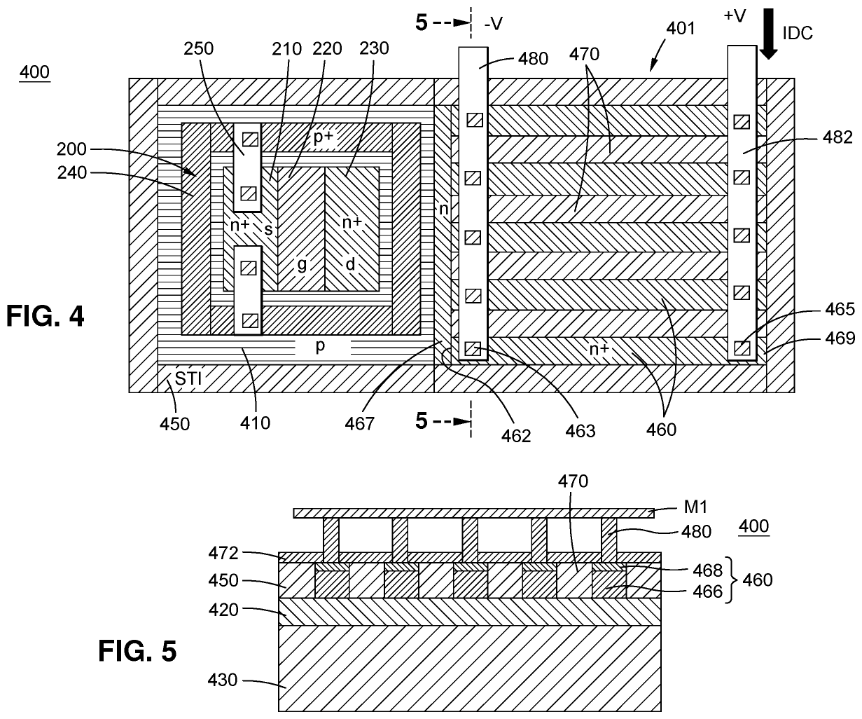

FIG. 4 is a top view of another SOI die 400 including a cooling structure 401 according to an embodiment of the present disclosure. FIG. 5 is a cross-sectional view taken along the line 5-5 in FIG. 4. Like the SOI die 100, the SOI die 400 may include a semiconductor device such as the illustrated NMOS transistor 200, which may be placed inside a P-well 410 that is surrounded by an isolation trench 450 and disposed on a BOX layer 420 formed in a semiconductor substrate 430 that are the same as the P-well 110, isolation trench 150, BOX layer 120, and semiconductor substrate 130 of the SOI die 100 shown in FIGS. 1-3. Except as otherwise indicated, the cooling structure 401 of the SOI die 400 may be the same as the cooling structure 101 of the SOI die 100 and may be defined by a plurality of semiconductor strips 460 separated by isolation trenches 470 and connected by first and second metal interconnects 480, 482 through a stop layer 472 that are the same as the semiconductor strips 160, isolation trenches 170, first and second metal interconnects 180, 182, and stop layer 172 of the SOI die 100 of FIGS. 1-3, with the semiconductor strips 460 each having first and second ends 462, 464 and first and second connection points 463, 465 and comprising an N-well 466 and optional N+ doped layer 468 that are the same as the first and second ends 162, 164, first and second connection points 163, 165, N-well 166, and N+ doped layer 168 described above.

The cooling structure 401 of the SOI die 400 differs from the cooling structure 101 of FIGS. 1-3 as follows. Whereas each of the N-wells 166 of the semiconductor strips 160 abuts the device P-well 110 as shown in FIGS. 1 and 3, the N-wells 466 of FIG. 4 are connected to each other at the first ends 462 of the strips 460 to form a shared N-well 467 that abuts the device P-well 410, with the strips 460 themselves being slightly shorter than the strips 160 of FIG. 1. The shared N-well 467 may result in a higher level of heat transfer from the N-metal junctions (connection points 463) where cooling occurs by the Peltier effect.

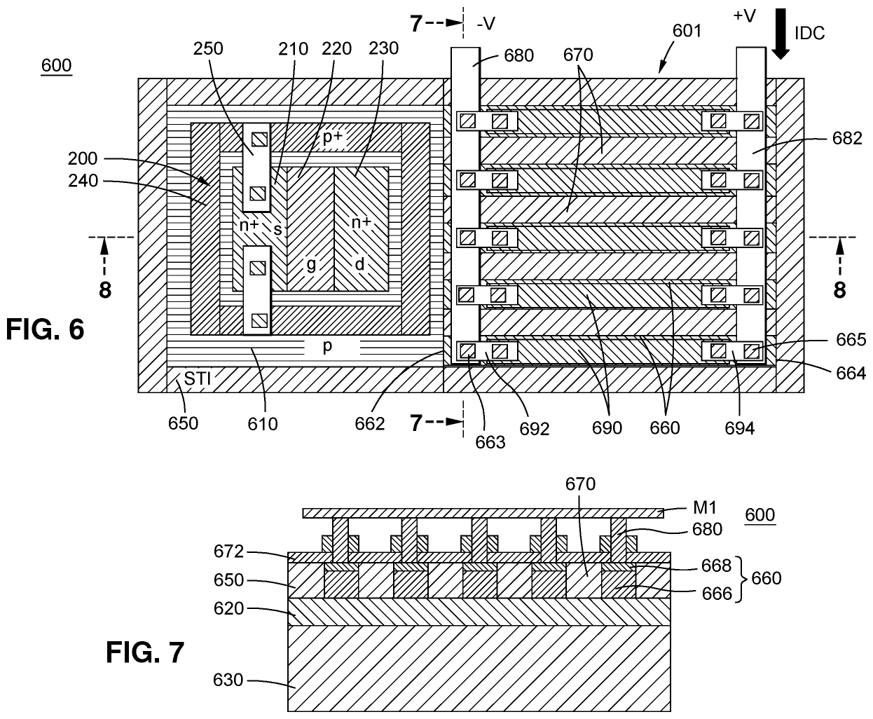

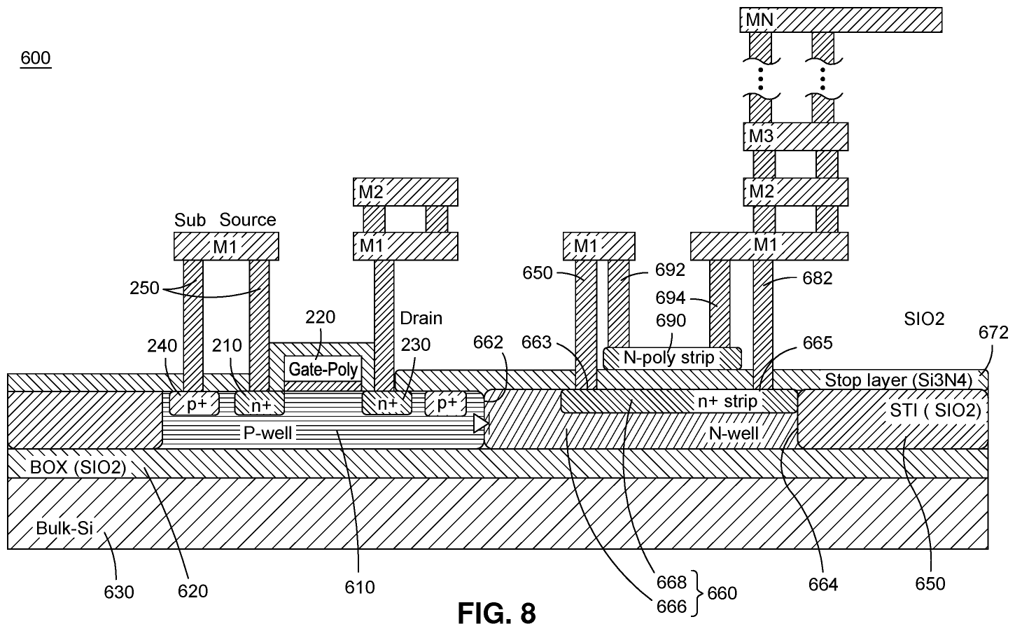

FIG. 6 is a top view of another SOI die 600 including a cooling structure 601 according to an embodiment of the present disclosure. FIGS. 7 and 8 are cross-sectional views taken along the line 7-7 and 8-8 in FIG. 6, respectively. Like the SOI die 100, the SOI die 600 may include a semiconductor device such as the illustrated NMOS transistor 200, which may be placed inside a P-well 610 that is surrounded by an isolation trench 650 and disposed on a BOX layer 620 formed in a semiconductor substrate 630 that are the same as the P-well 110, isolation trench 150, BOX layer 120, and semiconductor substrate 130 of the SOI die 100 shown in FIGS. 1-3. Except as otherwise indicated, the cooling structure 601 of the SOI die 600 may be the same as the cooling structure 101 of the SOI die 100 and may be defined by a plurality of semiconductor strips 660 separated by isolation trenches 670 and connected by first and second metal interconnects 680, 682 through a stop layer 672 that are the same as the semiconductor strips 160, isolation trenches 170, first and second metal interconnects 180, 182, and stop layer 172 of the SOI die 100 of FIGS. 1-3, with the semiconductor strips 660 each having first and second ends 662, 664 and first and second connection points 663, 665 and comprising an N-well 666 and optional N+ doped layer 668 that are the same as the first and second ends 162, 164, first and second connection points 163, 165, N-well 166, and N+ doped layer 168 described above.

The cooling structure 601 of the SOI die 600 differs from the cooling structure 101 of FIGS. 1-3 in the inclusion of a plurality of N-doped polysilicon strips 690. As shown in FIGS. 6-8, each of the N-doped polysilicon strips 690 may be disposed on top of a corresponding one of the semiconductor strips 660 and separated therefrom by a dielectric such as the stop layer 672 so as to be electrically isolated from the strip 660. In the case of each of the semiconductor strips 660 that electrically connects the first and second interconnects 680, 682 (all of the strips 660 in the example of FIG. 6), the corresponding one of the N-doped polysilicon strips 690 may be electrically (and thermally) connected to the first and second metal interconnects 680, 682 in parallel with the semiconductor strip 660. This structure may effectively increase the cross-section of heat transfer from the N-metal junctions (connection points 663) where cooling occurs by the Peltier effect. As shown in FIGS. 6 and 8, the parallel connections between the semiconductor strips 660 and corresponding polysilicon strips 690 may be made by metal contacts 692, 694 formed in the same metal layer M1 in which the metal interconnects 680, 682 are formed.

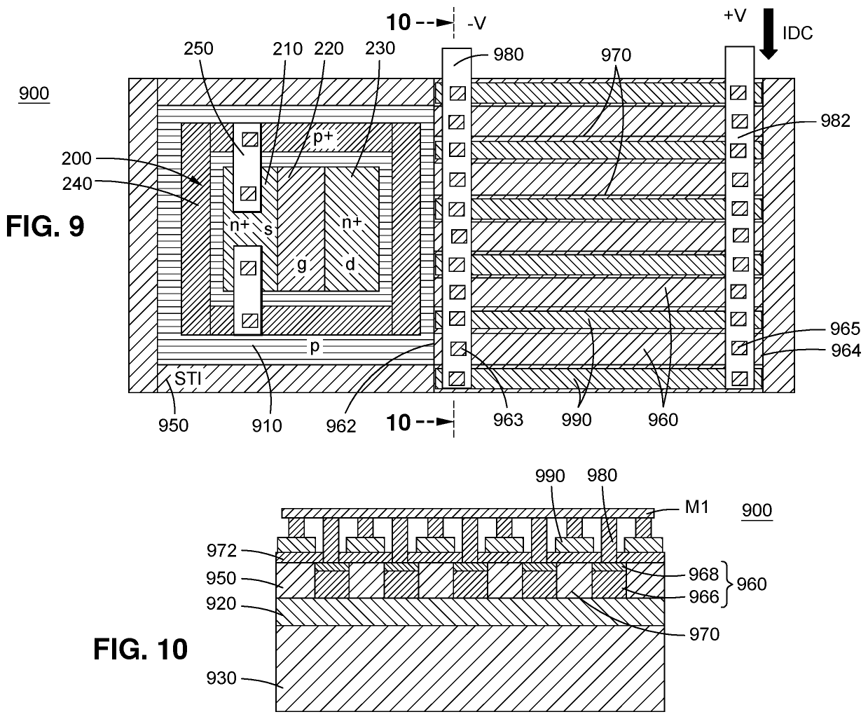

FIG. 9 is a top view of another SOI die 900 including a cooling structure 901 according to an embodiment of the present disclosure. FIG. 10 is a cross-sectional view taken along the line 10-10 in FIG. 9. Like the SOI die 100, the SOI die 900 may include a semiconductor device such as the illustrated NMOS transistor 200, which may be placed inside a P-well 910 that is surrounded by an isolation trench 950 and disposed on a BOX layer 920 formed in a semiconductor substrate 930 that are the same as the P-well 110, isolation trench 150, BOX layer 120, and semiconductor substrate 130 of the SOI die 100 shown in FIGS. 1-3. Except as otherwise indicated, the cooling structure 901 of the SOI die 900 may be the same as the cooling structure 101 of the SOI die 100 and may be defined by a plurality of semiconductor strips 960 separated by isolation trenches 970 and connected by first and second metal interconnects 980, 982 through a stop layer 972 that are the same as the semiconductor strips 160, isolation trenches 170, first and second metal interconnects 180, 182, and stop layer 172 of the SOI die 100 of FIGS. 1-3, with the semiconductor strips 960 each having first and second ends 962, 964 and first and second connection points 963, 965 and comprising an N-well 966 and optional N+ doped layer 968 that are the same as the first and second ends 162, 164, first and second connection points 163, 165, N-well 166, and N+ doped layer 168 described above.

The cooling structure 901 of the SOI die 900 differs from the cooling structure 101 of FIGS. 1-3 in the inclusion of a plurality of N-doped polysilicon strips 990. The N-doped polysilicon strips 990 may be functionally the same as the N-doped polysilicon strips 690 described above in relation to FIGS. 6-8. However, as shown in FIGS. 9 and 10, each of the N-doped polysilicon strips 990 may be disposed on top of a corresponding one of the isolation trenches 970 between the semiconductor strips 960 and separated therefrom by a dielectric such as the stop layer 972 so as to be electrically isolated from the adjacent strips 960. In the case of each of the semiconductor strips 960 that electrically connects the first and second interconnects 980, 982 (all of the strips 960 in the example of FIG. 9), the corresponding one of the N-doped polysilicon strips 990 may be electrically (and thermally) connected to the first and second metal interconnects 980, 982 in parallel with the semiconductor strip 960. In the example of FIGS. 9 and 10, there is one more polysilicon strip 990 than there are semiconductor strips 960 such that each of the semiconductor strips 960 is surrounded on both sides by a polysilicon strip 990. Like the related structure of FIGS. 6-8, this structure may effectively increase the cross-section of heat transfer from the N-metal junctions (connection points 963) where cooling occurs by the Peltier effect. However, the alternating structure of FIGS. 9 and 10, with polysilicon strips 990 placed between semiconductor strips 960 on the isolation trenches 970, may preferably allow the polysilicon strips 990 to be placed closer to the NMOS transistor 200 for improved cooling. As shown in FIGS. 9 and 10, the parallel connections between the semiconductor strips 960 and corresponding polysilicon strips 990 may be to the same metal interconnects 680, 682 formed in the metal layer M1.

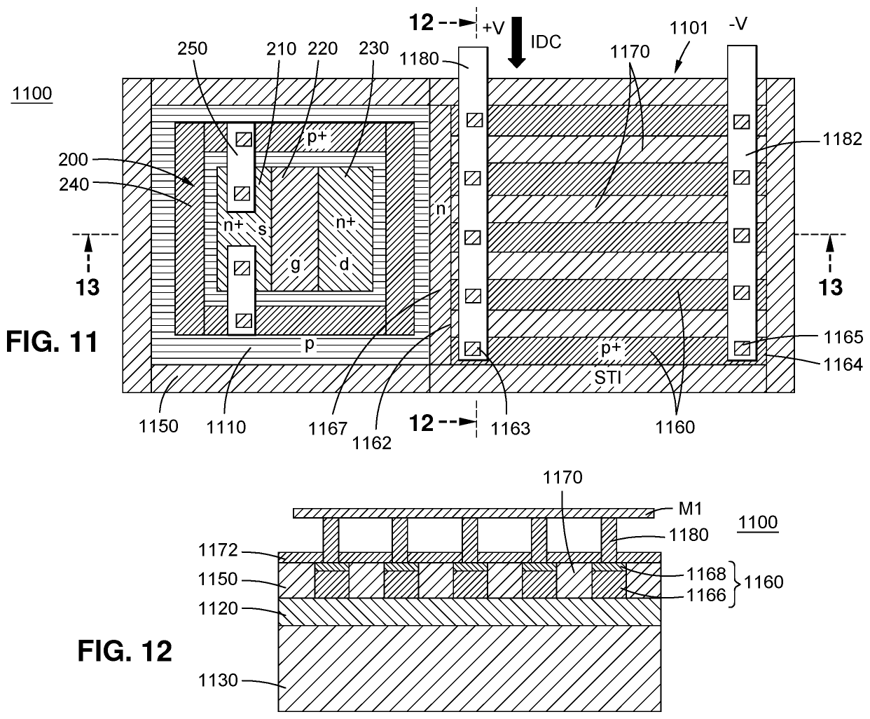

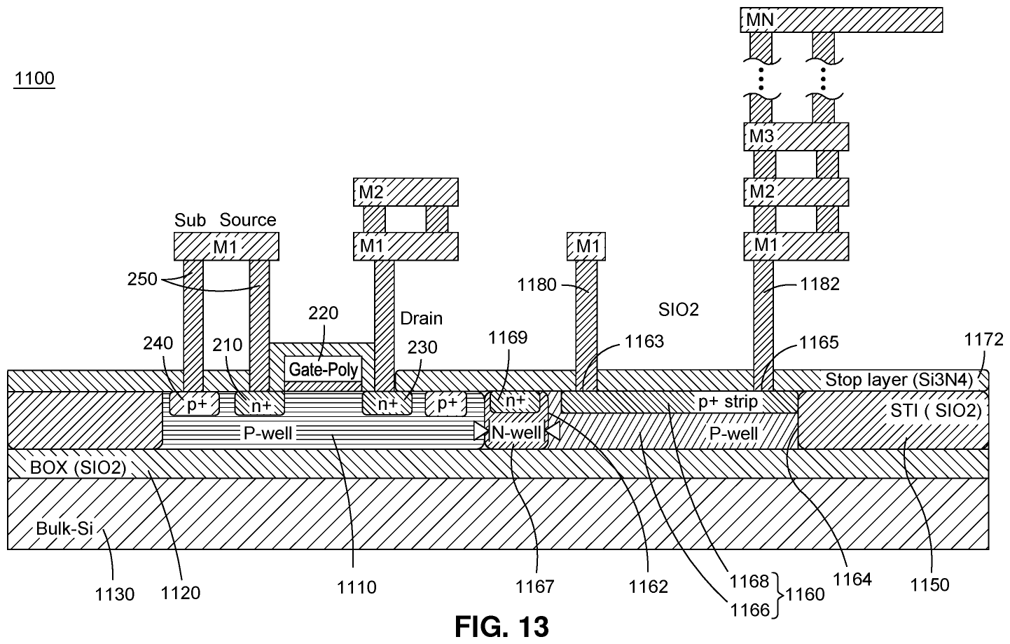

FIG. 11 is a top view of another SOI die 1100 including a cooling structure 1101 according to an embodiment of the present disclosure. FIGS. 12 and 13 are cross-sectional views taken along the lines 12-12 and 13-13 in FIG. 11. Like the SOI die 100, the SOI die 1100 may include a semiconductor device such as the illustrated NMOS transistor 200, which may be placed inside a P-well 1110 that is surrounded by an isolation trench 1150 and disposed on a BOX layer 1120 formed in a semiconductor substrate 1130 that are the same as the P-well 110, isolation trench 150, BOX layer 120, and semiconductor substrate 130 of the SOI die 100 shown in FIGS. 1-3. Except as otherwise indicated, the cooling structure 1101 of the SOI die 1100 may be the same as the cooling structure 101 of the SOI die 100 and may be defined by a plurality of semiconductor strips 1160 separated by isolation trenches 1170 and connected by first and second metal interconnects 1180, 1182 through a stop layer 1172 that are the same as the semiconductor strips 160, isolation trenches 170, first and second metal interconnects 180, 182, and stop layer 172 of the SOI die 100 of FIGS. 1-3, with the semiconductor strips 1160 each having first and second ends 1162, 1164 and first and second connection points 1163, 1165 that are the same as the first and second ends 162, 164 and first and second connection points 163, 165 described above.

The cooling structure 1101 of the SOI die 1100 differs from the cooling structure 101 of FIGS. 1-3 in that the semiconductor strips 1160 comprise a P-well 1166 and optional P+ doped layer 1168 instead of the N-well 166 and optional N+ doped layer 168. In this regard, the semiconductor strips 1160 may be referred to as P-strips or P-type whereas the semiconductor strips 160, 460, 660, 960 described above may be referred to as N-strips or N-type. Because the semiconductor strips 1160 comprise P-wells 1166 instead of N-wells 166, the abutment between the strips 1160 and the device P-well 1110 would not result in P-N junction contact as illustrated in FIG. 3. Therefore, in order to prevent the DC current in the strips 1160 from flowing to the NMOS transistor 200, the cooling structure 1101 of the SOI die 1110 may further comprise an N-well 1167 formed between and abutting the device P-well 1110 and the P-wells 1166 of each of the semiconductor strips 1160 (see FIGS. 11 and 13). The resulting P-N junction contact between the device P-well 1110 and the N-well 1167 may function as a diode as schematically depicted in FIG. 13, thus preventing the DC current in the strips 1160 from flowing to the NMOS transistor 200. An optional N+ doped layer 1169 may be disposed inside the N-well 1167.

In the example of FIGS. 11-13, where the strips 1160 are P-type (each comprising a P-well 1166 and optional P+ strip 1168), the DC current IDC is generated so as to flow in the opposite direction compared to the above examples (e.g. by applying opposite polarity voltage +V, −V), namely from the first metal interconnect 1180 (i.e. the one that is closer to the device 200) through the plurality of semiconductor strips 1160 to the second metal interconnect 1182 (i.e. the one that is farther from the device 200), with the DC current IDC flowing through the plurality of semiconductor strips 1160 in parallel. As a result, the metal-P junction where current flows from metal to P-type semiconductor at the first connection points 1163 (where the first metal interconnect 1180 meets each strip 1160) becomes cooler by the Peltier effect, while the P-metal junction where current flows from P-type semiconductor to metal at the second connection points 1165 (where the second metal interconnect 1182 meets each strip 1160) becomes warmer by the Peltier effect.

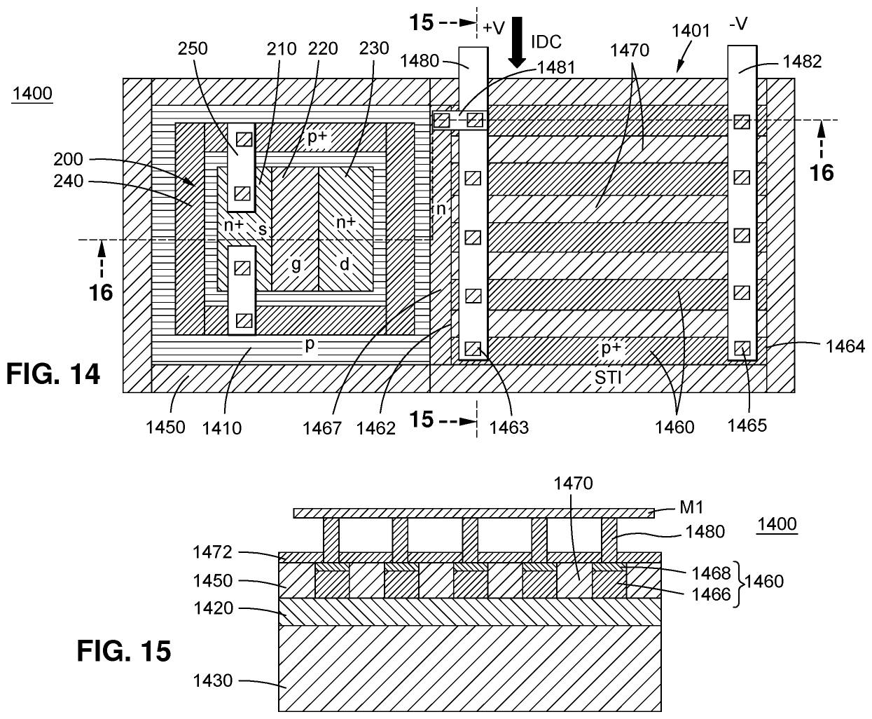

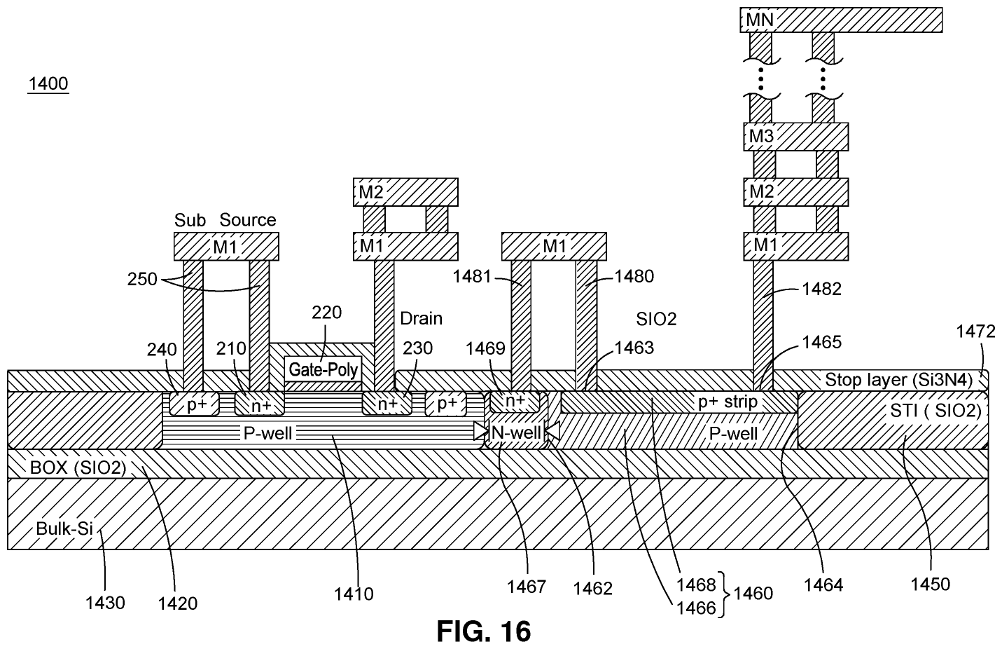

FIG. 14 is a top view of another SOI die 1400 including a cooling structure 1401 according to an embodiment of the present disclosure. FIGS. 15 and 16 are cross-sectional views taken along the lines 15-15 and 16-16 in FIG. 14, respectively. Like the SOI die 100, the SOI die 1400 may include a semiconductor device such as the illustrated NMOS transistor 200, which may be placed inside a P-well 1410 that is surrounded by an isolation trench 1450 and disposed on a BOX layer 1420 formed in a semiconductor substrate 1430 that are the same as the P-well 110, isolation trench 150, BOX layer 120, and semiconductor substrate 130 of the SOI die 100 shown in FIGS. 1-3. Except as otherwise indicated, the cooling structure 1401 of the SOI die 1400 may be the same as the cooling structure 101 of the SOI die 100 and may be defined by a plurality of semiconductor strips 1460 separated by isolation trenches 1470 and connected by first and second metal interconnects 1480, 1482 through a stop layer 1472 that are the same as the semiconductor strips 160, isolation trenches 170, first and second metal interconnects 180, 182, and stop layer 172 of the SOI die 100 of FIGS. 1-3, with the semiconductor strips 1160 each having first and second ends 1462, 1464 and first and second connection points 1463, 1465 that are the same as the first and second ends 162, 164 and first and second connection points 163, 165 described above.

More particularly, the cooling structure 1401 of the SOI die 1400 may be the same as the cooling structure 1101 of the SOI die 1100 shown in FIGS. 11-13, with each of the plurality of semiconductor strips 1460 comprising a P-well 1466 and optional P+ doped layer 1468 corresponding to the P-well 1166 and P+ doped layer of each of the P-type strips 1160 of FIGS. 11-13. Likewise, the cooling structure 1401 of the SOI die 1400 may similarly include an N-well 1467 with optional N+ doped layer 1469 formed between and abutting the device P-well 1410 and the P-wells 1466 of each of the semiconductor strips 1460 (see FIGS. 14 and 16), corresponding to the N-well 1167 and N+ doped layer 1169 shown in FIGS. 11 and 13. The example of FIGS. 14-16 differs from the example of FIGS. 11-13 in the addition of one or more contacts 1481 electrically connecting the P-well 1466 of at least one of the semiconductor strips 1460 to the N-well 1467. By including one or more contacts 1481 (e.g. one for each of the plurality of strips 1460), the possibility of latch-up caused by the floating N-well 1167 may be reduced or eliminated.

In the above examples, it is described that a plurality of N-doped polysilicon strips 690, 990 may be disposed on top of a corresponding one of the semiconductor strips 660 (see FIGS. 6-8) or isolation trench 970 (see FIGS. 9 and 10) and separated therefrom by a dielectric such as the stop layer 672, 972. In the case of the P-type strips 1160, 1460 of FIGS. 11-16, the same structures may be used, but with P-doped polysilicon strips in place of the N-doped polysilicon strips 690, 990. In the same way, a parallel electrical and thermal connection can be made between the first and second metal interconnects 1180, 1182 or first and second metal interconnects 1480, 1482, such that the cross-section of heat transfer from the metal-P junctions (connection points 1163, 1463) where cooling occurs by the Peltier effect can be effectively increased.

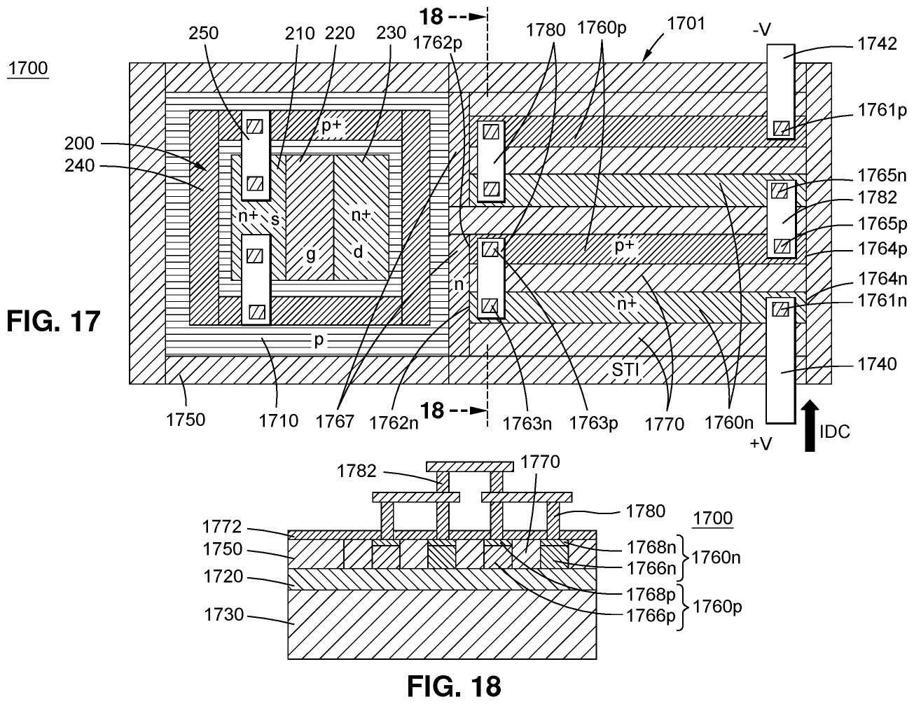

FIG. 17 is a top view of another SOI die 1700 including a cooling structure 1701 according to an embodiment of the present disclosure. FIG. 18 is a cross-sectional view taken along the line 18-18 in FIG. 17. Like the SOI die 100, the SOI die 1100 may include a semiconductor device such as the illustrated NMOS transistor 200, which may be placed inside a P-well 1710 that is surrounded by an isolation trench 1750 and disposed on a BOX layer 1720 formed in a semiconductor substrate 1730 that are the same as the P-well 110, isolation trench 150, BOX layer 120, and semiconductor substrate 130 of the SOI die 100 shown in FIGS. 1-3. Except as otherwise indicated, the cooling structure 1701 of the SOI die 1700 may be the same as the cooling structure 101 of the SOI die 100 and may be defined by a plurality of semiconductor strips 1760 (namely strips 1760n and 1760p) separated by isolation trenches 1770 and connected by first and second metal interconnects 1780, 1782 through a stop layer 1772 that are the same as the semiconductor strips 160, isolation trenches 170, first and second metal interconnects 180, 182, and stop layer 172 of the SOI die 100 of FIGS. 1-3, with the semiconductor strips 1760 each having a first end 1762 (i.e. 1762n and 1762p), a second end 1764 (i.e. 1764n and 1764p), a first connection point 1763 (i.e. 1763n and 1763p), and a second connection point 1765 (i.e. 1765n and 1765p) that are the same as the first and second ends 162, 164 and first and second connection points 163, 165 described above.

The cooling structure 1701 of the SOI die 1700 differs from the cooling structure 101 of FIGS. 1-3 in that the plurality of semiconductor strips 1760 comprises two or more first semiconductor strips 1760n of N-type arranged alternatingly with two or more second semiconductor strips 1760p of P-type. In this regard, each of the first semiconductor strips 1760n may comprise an N-well 1766n and optional N+ doped layer 1768n like the N-well 166 and optional N+ doped layer 168 of FIGS. 1-3, while each of the second semiconductor strips 1760p comprises a P-well 1766n and optional P+ doped layer 1768p instead of the N-well 166 and optional N+ doped layer 168 (similar to the P-well 1166 and optional P+ layer 1168 of FIGS. 11-13). The P-type strips and N-type strips may have different heat transfer effectiveness. Because the semiconductor strips 1760p comprise P-wells 1766 instead of N-wells 166, the abutment between the strips 1760p and the device P-well 1710 would not result in P-N junction contact as illustrated in FIG. 3. Therefore, in order to prevent the DC current in the strips 1760 from flowing to the NMOS transistor 200, the cooling structure 1701 of the SOI die 1710 may further comprise one or more N-wells 1767 formed between and abutting the device P-well 1710 and the P-wells 1766p of each of the second (P-type) semiconductor strips 1760p (see FIG. 17). The resulting P-N junction contact between the device P-well 1710 and the N-well 1767 may function as a diode in the same way as schematically depicted in FIG. 13, thus preventing the DC current in the strips 1760p from flowing to the NMOS transistor 200. It is noted that additional connections for preventing latch-up, like the one or more contacts 1481 shown in FIG. 14, may be unnecessary in this case. An optional N+ doped layer like the optional N+ doped layer 1169 may be disposed inside the N-well 1767.

In the example of FIGS. 17 and 18, where the strips 1760 are both P-type and N-type, the DC current IDC is generated so as to flow through the strips 1760 in series rather than in parallel as in the above examples. In this regard, the cooling structure 1701 may include a first metal terminal 1740 connected to one of the first semiconductor strips 1760n at a terminal point 1761n thereof, the terminal point 1761n being closer to the second end 1764n than to the first end 1762n of the strip 1760n. The cooling structure 1701 may further include a second metal terminal 1742 connected to one of the second semiconductor strips 1760p at a terminal point 1761p thereof, the terminal point 1761p being closer to the second end 1764p than to the first end 1762p of the strip 1760p. In order to generate the DC current IDC in the plurality of semiconductor strips 1760 to produce the cooling effect, a voltage may be applied via the metal terminals 1740, 1742 as represented by +V and −V in FIG. 17. It should be noted that, unlike the example shown in FIG. 1 and the other examples described above, the first and second metal interconnects 1780, 1782 connecting the strips 1760 in series do not also serve as the terminals 1740, 1742 for applying the voltage in the example of FIG. 17. Note that the terminals 1740, 1742 are omitted in FIG. 18.

The DC current IDC may flow from the first metal terminal 1740 through the plurality of semiconductor strips 1760 and through the first and second metal interconnects 1780, 1782 to the second metal terminal 1742, with the DC current IDC flowing through first and second semiconductor strips 1760 in series within each pair of a first semiconductor strip 1760n and a second semiconductor strip 1760p. Moreover, each first metal interconnect 1780 (i.e. the one(s) closer to the device 200) may be arranged to connect a first (N-type) semiconductor strip 1760n to a second (P-type) semiconductor strip 1760p in the direction of the current IDC, while each second metal interconnect 1782 (i.e. the one(s) farther from the device 200) may be arranged to connect one pair of semiconductor strips 1760n, 1760p to another, that is, to connect a second (P-type) semiconductor strip 1760p to a first (N-type) semiconductor strip 1760p in the direction of the current IDC. As a result, the N-metal junction(s) where current flows from N-type semiconductor to metal at the first connection point(s) 1763n (where the first metal interconnect(s) 1780 meet each N-type strip 1760n) and the metal-P junction(s) where current flows from metal to P-type semiconductor at the first connection point(s) 1763p (where the first metal interconnect(s) 1780 meet each P-type strip 1760p) become cooler by the Peltier effect. At the same time, the P-metal junction(s) where current flows from P-type semiconductor to metal at the second connection point(s) 1765p (where the second metal interconnect(s) 1782 meet each P-type strip 1760p) and at the second terminal point 1761p (where the second terminal 1742 meets the last P-strip 1760p) become warmer by the Peltier effect, and the metal-N junction(s) where current flows from metal to N-type semiconductor at the second connection point(s) 1765n (where the second metal interconnect(s) 1782 meet each N-type strip 1760n) and at the first terminal point 1761n (where the first terminal 1740 meets the initial N-strip 1760n) likewise become warmer by the Peltier effect.

In some cases, depending on the desired amount of cooling and the layout of the SOI die 1700, it may be possible to omit the second metal interconnect(s) 1782 entirely. For example, in the case of only a single first (N-type) semiconductor strip 1760n and a single second (P-type) semiconductor strip 1760p, the DC current IDC may flow from a first terminal 1740, through the semiconductor strip 1760n, through a single first metal interconnect 1780 near the device 200, through the semiconductor strip 1760p, and to the second terminal 1742.

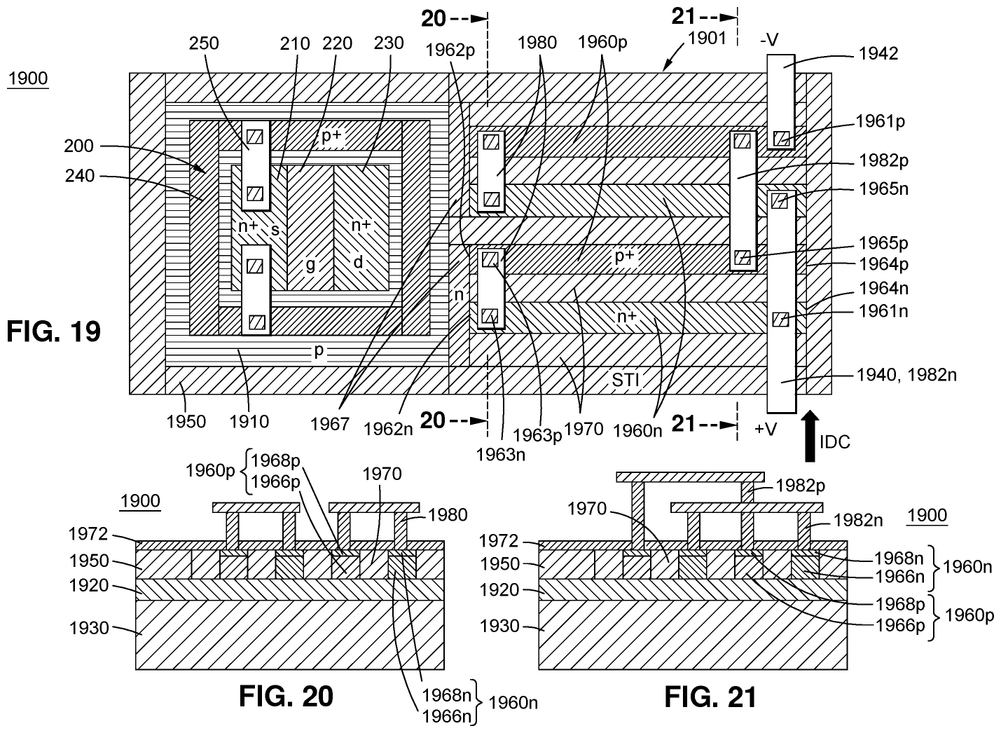

FIG. 19 is a top view of another SOI die 1900 including a cooling structure 1901 according to an embodiment of the present disclosure. FIGS. 20 and 21 are cross-sectional views taken along the lines 20-20 and 21-21 in FIG. 19. Like the SOI die 100, the SOI die 1900 may include a semiconductor device such as the illustrated NMOS transistor 200, which may be placed inside a P-well 1910 that is surrounded by an isolation trench 1950 and disposed on a BOX layer 1920 formed in a semiconductor substrate 1930 that are the same as the P-well 110, isolation trench 150, BOX layer 120, and semiconductor substrate 130 of the SOI die 100 shown in FIGS. 1-3. Except as otherwise indicated, the cooling structure 1901 of the SOI die 1900 may be the same as the cooling structure 101 of the SOI die 100 and may be defined by a plurality of semiconductor strips 1960 (namely strips 1960n and 1960p) separated by isolation trenches 1970 and connected by first and second metal interconnects 1980, 1982 (i.e. 1982n and 1982p) through a stop layer 1972 that are the same as the semiconductor strips 160, isolation trenches 170, first and second metal interconnects 180, 182, and stop layer 172 of the SOI die 100 of FIGS. 1-3, with the semiconductor strips 1960 each having first and second ends 1962 (i.e. 1962n and 1962p), 1964 (i.e. 1964n and 1964p) and first and second connection points 1163 (i.e. 1963n and 1963p), 1965 (i.e. 1965n and 1965p) that are the same as the first and second ends 162, 164, first and second connection points 163, 165 described above.

More particularly, the cooling structure 1901 of the SOI die 1900 may be the same as the cooling structure 1701 of the SOI die 1700 shown in FIGS. 17 and 18, with the plurality of semiconductor strips 1960 comprising two or more first semiconductor strips 1960n of N-type arranged alternatingly with two or more second semiconductor strips 1960p of P-type. In this regard, each of the first semiconductor strips 1960n may comprise an N-well 1966n and optional N+ doped layer 1968n like the N-well 1766n and optional N+ doped layer 1768n of FIGS. 17 and 18, while each of the second semiconductor strips 1960p comprises a P-well 1966n and optional P+ doped layer 1968p like the P-well 1766p and optional P+ layer 1768p of FIGS. 17 and 18. Likewise, the cooling structure 1901 of the SOI die 1910 may further comprise one or more N-wells 1967 (with optional N+ doped layer) formed between and abutting the device P-well 1910 and the P-wells 1966p of each of the second (P-type) semiconductor strips 1960p (see FIG. 19). Like the cooling structure 1701 of FIG. 17, the cooling structure 1901 of FIGS. 19-21 may include a first metal terminal 1940 connected to one of the first semiconductor strips 1960n at a terminal point 1961n thereof, the terminal point 1961n being closer to the second end 1964n than to the first end 1962n of the strip 1960n. The cooling structure 1901 may further include a second metal terminal 1942 connected to one of the second semiconductor strips 1960p at a terminal point 1961p thereof, the terminal point 1961p being closer to the second end 1964p than to the first end 1962p of the strip 1960p. In order to generate the DC current IDC in the plurality of semiconductor strips 1960 to produce the cooling effect, a voltage may be applied via the metal terminals 1940, 1942 as represented by +V and −V in FIG. 19. Unlike the example of FIG. 17, the example cooling structure 1901 shown in FIG. 19 includes one metal terminal 1940 for applying voltage that also serves as one of the metal interconnects 1982 connecting the strips 1960, namely the second metal interconnect 1982n that connects two of the first (N-type) semiconductor strips 1960n. Note that the second terminal 1942 is omitted in FIG. 21 (and that both terminals 1940, 1942 and second metal interconnects 1982 are omitted in FIG. 20).

As in the example of FIG. 17, the DC current IDC of FIG. 19 may flow from the first metal terminal 1940 through the plurality of semiconductor strips 1960 and through the first and second metal interconnects 1980, 198 2 to the second metal terminal 1942, with the DC current IDC flowing through first and second semiconductor strips 1960 in series within each pair of a first semiconductor strip 1960n and a second semiconductor strip 1960p. Also as in FIG. 17, each first metal interconnect 1980 (i.e. the one(s) closer to the device 200) may be arranged to connect a first (N-type) semiconductor strip 1960n to a second (P-type) semiconductor strip 1960p in the direction of the current IDC. However, as shown in FIGS. 19 and 21, the cooling structure 1901 may differ from that of FIG. 17 in that the second metal interconnects 1982 connecting the semiconductor strips 1960 at second ends 1964 thereof (i.e. far from the NMOS transistor 200) come in two types: N-strip metal interconnects 1982n that connect first (N-type) semiconductor strips 1960n and P-strip metal interconnects 1982p that connect second (P-type) semiconductor strips 1960p. For example, as shown, an N-strip metal interconnect 1982n may connect two first (N-type) semiconductor strips 1960n on either side of a second (P-type) semiconductor strip 1960p without making an electrical connection with the second (P-type) semiconductor strip 1960p. Likewise, a P-strip metal interconnect 1982p may connect two second (P-type) semiconductor strips 1960p on either side of a first (N-type) semiconductor strip 1960n without making an electrical connection with the first (N-type) semiconductor strip 1960n.

In general, and as exemplified by FIGS. 19-21, the first and second metal interconnects 1980, 1982 may be arranged such that the DC current IDC flows through different pairs of a first semiconductor strip 1960n and a second semiconductor strip 1960p in parallel. In particular, whereas the second metal interconnects 1782 of FIG. 17 (i.e. the one(s) farther from the device 200) may be arranged to connect one pair of semiconductor strips 1760n, 1760p to another in series, the second metal interconnects 1982n, 1982p of FIGS. 19-21 may be arranged to connect one pair of semiconductor strips 1960n 1960p to another in parallel. This may advantageously reduce the electrical resistance between the +V and −V terminals 1940, 1942, thus reducing the voltage necessary for adequate cooling. As a result, a low-voltage DC current source may be used to apply the voltage rather than a high voltage source.

Specifically, in the example of FIGS. 19-21, the N-metal junction(s) where current flows from N-type semiconductor to metal at the first connection point(s) 1963n (where the first metal interconnect(s) 1980 meet each N-type strip 1960n) and the metal-P junction(s) where current flows from metal to P-type semiconductor at the first connection point(s) 1963p (where the first metal interconnect(s) 1980 meet each P-type strip 1960p) become cooler by the Peltier effect. At the same time, the P-metal junction(s) where current flows from P-type semiconductor to metal at the second connection point(s) 1965p (where the P-strip metal interconnect(s) 1982p meet each P-type strip 1960p) and at the second terminal point 1961p (where the second terminal 1942 meets the last P-strip 1960p) become warmer by the Peltier effect, and the metal-N junction(s) where current flows from metal to N-type semiconductor at the second connection point(s) 1965n (where the N-strip metal interconnect(s) 1982n meet each N-type strip 1960n) and at the first terminal point 1961n (where the first terminal 1940 meets the initial N-strip 1960n) likewise become warmer by the Peltier effect. It should be noted that the existence of any metal-P junctions on the right-hand side of FIG. 19 (such as in the last P-strip 1960 adjacent the second terminal point 1961p) may create negligible cooling that is outweighed by the warming effect. The negligible cooling may be completely avoided by directly connecting the P-strip metal interconnect 1982p to the second terminal 1942.

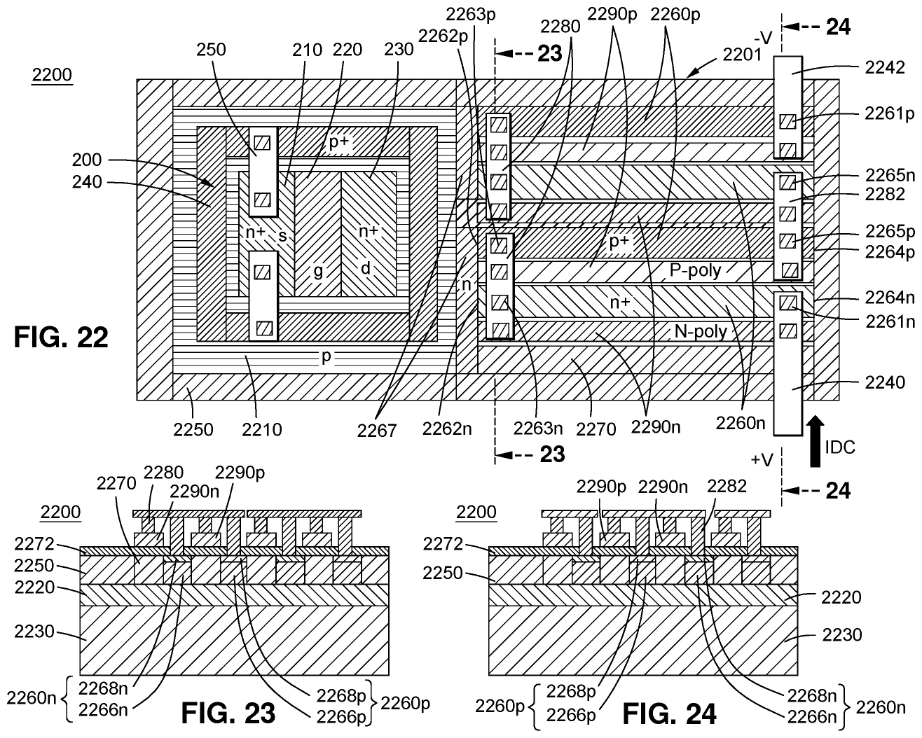

FIG. 22 is a top view of another SOI die 2200 including a cooling structure according to an embodiment of the present disclosure. FIGS. 23 and 24 are cross-sectional views taken along the lines 23-23 and 24-24 in FIG. 22. Like the SOI die 100, the SOI die 2200 may include a semiconductor device such as the illustrated NMOS transistor 200, which may be placed inside a P-well 2210 that is surrounded by an isolation trench 2250 and disposed on a BOX layer 2220 formed in a semiconductor substrate 2230 that are the same as the P-well 110, isolation trench 150, BOX layer 120, and semiconductor substrate 130 of the SOI die 100 shown in FIGS. 1-3. Except as otherwise indicated, the cooling structure 2201 of the SOI die 2200 may be the same as the cooling structure 101 of the SOI die 100 and may be defined by a plurality of semiconductor strips 2260 (namely strips 2260n and 2260p) separated by isolation trenches 2270 and connected by first and second metal interconnects 2280, 2282 through a stop layer 2272 that are the same as the semiconductor strips 160, isolation trenches 170, first and second metal interconnects 180, 182, and stop layer 172 of the SOI die 100 of FIGS. 1-3, with the semiconductor strips 2260 each having first and second ends 2262 (i.e. 2262n and 2262p), 2264 (i.e. 2264n and 2264p) and first and second connection points 2263 (i.e. 2263n and 2263p), 2265 (i.e. 2265n and 2265p) that are the same as the first and second ends 162, 164, first and second connection points 163, 165 described above.

More particularly, the cooling structure 2201 of the SOI die 2200 may be the same as the cooling structure 1701 of the SOI die 1700 shown in FIGS. 17 and 18, with the plurality of semiconductor strips 2260 comprising two or more first semiconductor strips 2260n of N-type arranged alternatingly with two or more second semiconductor strips 2260p of P-type. In this regard, each of the first semiconductor strips 2260n may comprise an N-well 2266n and optional N+ doped layer 2268n like the N-well 1766n and optional N+ doped layer 1768n of FIGS. 17 and 18, while each of the second semiconductor strips 2260p comprises a P-well 2266n and optional P+ doped layer 2268p like the P-well 1766p and optional P+ layer 1768p of FIGS. 17 and 18. Likewise, the cooling structure 2201 of the SOI die 2210 may further comprise one or more N-wells 2267 (with optional N+ doped layer) formed between and abutting the device P-well 2210 and the P-wells 2266p of each of the second (P-type) semiconductor strips 2260p (see FIG. 22). Like the cooling structure 1701 of FIG. 17, the cooling structure 2201 of FIGS. 19-21 may include a first metal terminal 2240 connected to one of the first semiconductor strips 2260n at a terminal point 2261n thereof, the terminal point 2261n being closer to the second end 2264n than to the first end 2262n of the strip 2260n. The cooling structure 2201 may further include a second metal terminal 2242 connected to one of the second semiconductor strips 2260p at a terminal point 2261p thereof, the terminal point 2261p being closer to the second end 2264p than to the first end 2262p of the strip 2260p. In order to generate the DC current IDC in the plurality of semiconductor strips 2260 to produce the cooling effect, a voltage may be applied via the metal terminals 2240, 2242 as represented by +V and −V in FIG. 22. Like the example shown in FIG. 17 the first and second metal interconnects 2280, 2282 connecting the strips 2260 in series do not also serve as the terminals 2240, 2242 for applying the voltage in the example of FIG. 22.

The cooling structure 2201 of the SOI die 2200 differs from the cooling structure 1701 of FIGS. 17 and 18 in the inclusion of a plurality of N-doped polysilicon strips 2290n and P-doped polysilicon strips 2290p. The N-doped polysilicon strips 2290n may be functionally and structurally the same as the N-doped polysilicon strips 990 described above in relation to FIGS. 9 and 10 and may be disposed on top of a corresponding one of the isolation trenches 2270 between the semiconductor strips 2260 and separated therefrom by a dielectric such as the stop layer 2272 so as to be electrically isolated from the adjacent strips 2260. In the case of each of the first (N-type) semiconductor strips 2260n that electrically connects the first and second interconnects 2280, 2282, the corresponding one of the N-doped polysilicon strips 2290n may be electrically (and thermally) connected to the first and second metal interconnects 2280, 2282 in parallel with the strip 2260n. The P-doped polysilicon strips 2290p may be the same as the N-doped polysilicon strips 2290n except that they are P-doped rather than N-doped and provided in correspondence with the second (P-type) semiconductor strips 2260p rather than with the first (N-type) semiconductor strips 2260n. In the case of each of the second (P-type) semiconductor strips 2260p that electrically connects the first and second interconnects 2280, 2282, the corresponding one of the P-doped polysilicon strips 2290p may be electrically (and thermally) connected to the first and second metal interconnects 2280, 2282 in parallel with the strip 2260p. Like the related structures of FIGS. 6-10, this structure may effectively increase the cross-section of heat transfer from the N-metal and metal-P junctions (connection points 2263n and 2263p) where cooling occurs by the Peltier effect. As shown in FIGS. 22-24, the parallel connections between the semiconductor strips 2260 and corresponding polysilicon strips 2290n, 2290p may be to the same metal interconnects 2280, 2282 formed in the metal layer M1.

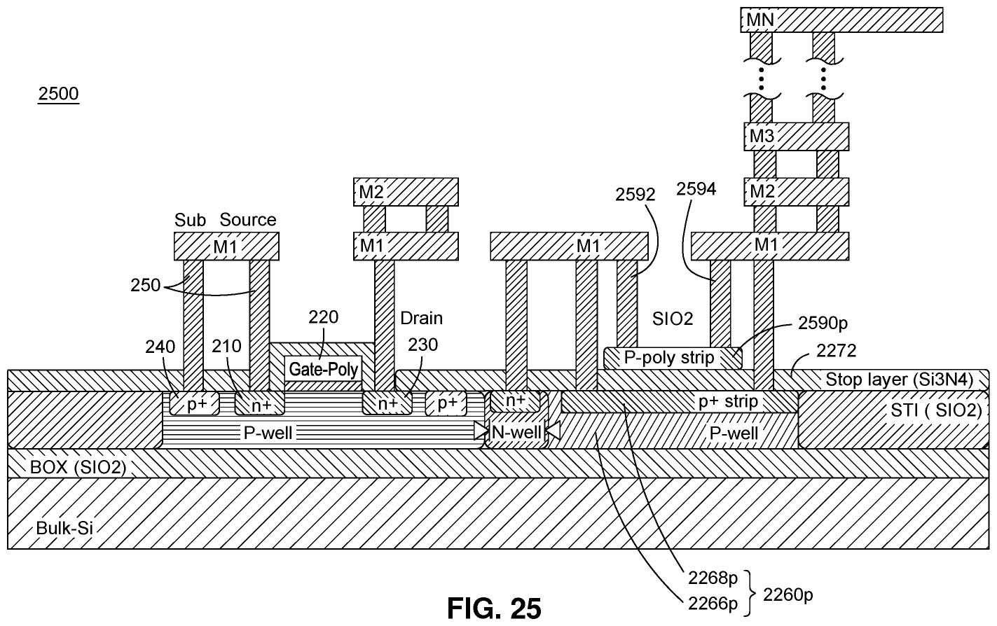

FIG. 25 is a cross-sectional view of a modified version 2500 of the SOI die 2200 of FIG. 22. Whereas the SOI die 2200 includes the N-doped polysilicon strips 2290n and 2290p placed alternatingly between the corresponding first and second semiconductor strips 2260n, 2260p on top of the isolation trench 2270, the modified SOI die 2500 of FIG. 25 (shown in cross-section only) instead places the N-doped and P-doped polysilicon strips 2590n, 2590p on top of the corresponding first and second semiconductor strips 2260n, 2260p and separated therefrom by a dielectric such as the stop layer 2272 like in the example SOI die 600 of FIGS. 6-8. In this variation, the parallel connections between the semiconductor strips 2260 and corresponding polysilicon strips 2590 (e.g. 2590n or 2590p) may be made by metal contacts 2292, 2294 formed in the metal layer M1 similar to the metal contacts 692, 694 shown in FIGS. 6 and 8. As noted above in relation to FIGS. 9 and 10, however, the alternating structure of FIGS. 22-24 in which the polysilicon strips 2290 are placed between semiconductor strips 2260 on the isolation trenches 2270 may preferably allow the polysilicon strips 2290 to be placed closer to the NMOS transistor 200 for improved cooling. While not separately illustrated, the N-doped and P-doped polysilicon strips of FIGS. 22-25 may also be used with the combined series/parallel structures exemplified by FIGS. 19-22.

Throughout the above disclosure, it is described that a current source or voltage source may be used to apply the voltage +V, −V and generate the DC current IDC in order to produce the Peltier effect to cool the semiconductor device 200. In this regard, a current source may be preferable because heat transfer from the cooling area (see FIG. 1, for example) is directly proportional to DC current flow through the cooling structure 101, etc. It should also be noted that heat transfer may be increased with the cross-section area of the N-type and/or P-type semiconductor strips 160, etc. In general, there is no need for special low thermal conductivity and high electrical conductivity of the N-type and/or P-type semiconductor strips 160, etc., as the Peltier effect may promote heat transfer by applying a particular level of DC current. The length of the semiconductor strips may be chosen as desired for the particular SOI die layout, with the metal interconnects/terminals preferably being placed far from the active transistor area in the case of relatively short strips. The foregoing may also be applicable to the poly-silicon strips. The orientation of the semiconductor strips 160 relative to the NMOS transistor channel may be either parallel or perpendicular. Moreover, the NMOS transistor structure may be surrounded by the cooling structure on all four sides.

The above description is given by way of example, and not limitation. Given the above disclosure, one skilled in the art could devise variations that are within the scope and spirit of the invention disclosed herein. For instance, although the examples illustrated in the present disclosure were NMOS transistors, similar features are also possible with PMOS transistors. Along these lines, cooling for other temperature sensitive circuits may be provided. The cooling structures disclosed herein may be utilized in connection with CMOS or Bi-CMOS processes, in addition to the SOI devices as described herein. It will be recognized by those having ordinary skill in the art, however, that the noted cooling effects possible with SOI devices may not be as efficient because of the high thermal conductivity properties of bulk CMOS. The various features of the embodiments disclosed herein can be used alone, or in varying combinations with each other and are not intended to be limited to the specific combination described herein. Thus, the scope of the claims is not to be limited by the illustrated embodiments.

What is claimed is:

1. A cooling structure for a silicon-on-insulator (SOI) semiconductor device, the cooling structure comprising:
a semiconductor substrate;
a buried oxide (BOX) layer formed in the semiconductor substrate;
a device P-well disposed on top of the BOX layer;
a plurality of semiconductor strips separated from each other by isolation trenches and each defined by first and second ends, each of the semiconductor strips extending away from the device P-well with the second end being farther than the first end from the device P-well;
a first metal interconnect electrically connecting a first set of the semiconductor strips at respective first connection points thereof, the first connection point of each of the strips of the first set being closer to the first end than to the second end;
a second metal interconnect electrically connecting a second set of the semiconductor strips at respective second connection points thereof, the second connection point of each of the strips of the second set being closer to the second end than to the first end, the second set having at least one of the semiconductor strips in common with the first set, the first and second metal interconnects being electrically connected to each other by the at least one of the semiconductor strips.

2. The cooling structure of claim 1, wherein each of the semiconductor strips comprises an N-well.

3. The cooling structure of claim 2, wherein each of the semiconductor strips comprises an N+doped layer disposed inside the N-well.

4. The cooling structure of claim 2, wherein each of the N-wells individually abuts the device P-well.

5. The cooling structure of claim 2, wherein the N-wells are connected to each other at the first ends of the strips to form a shared N-well that abuts the device P-well.

6. The cooling structure of claim 2, further comprising a plurality of N-doped polysilicon strips, each of the N-doped polysilicon strips being disposed on top of a corresponding one of the semiconductor strips and separated therefrom by a dielectric, wherein, for each of the at least one of the semiconductor strips that electrically connects the first and second interconnects, a corresponding one of the N-doped polysilicon strips is electrically connected to the first and second metal interconnects in parallel with the semiconductor strip.

7. The cooling structure of claim 2, further comprising a plurality of N-doped polysilicon strips, each of the N-doped polysilicon strips being disposed on top of a corresponding one of the isolation trenches and separated therefrom by a dielectric, wherein, for each of the at least one of the semiconductor strips that electrically connects the first and second interconnects, a corresponding one of the N-doped polysilicon strips is electrically connected to the first and second metal interconnects in parallel with the semiconductor strip.

8. The cooling structure of claim 2, further comprising a current source or voltage source configured to generate a DC current that flows from the second metal interconnect through the plurality of semiconductor strips to the first metal interconnect, the DC current flowing through the plurality of semiconductor strips in parallel.

9. The cooling structure of claim 1, wherein each of the semiconductor strips comprises a P-well, and the cooling structure further comprises an N-well formed between the device P-well and the P-wells of each of the semiconductor strips.

10. The cooling structure of claim 9, wherein each of the semiconductor strips comprises a P+ doped layer disposed inside the P-well.

11. The cooling structure of claim 9, further comprising a plurality of P-doped polysilicon strips, each of the P-doped polysilicon strips being disposed on top of a corresponding one of the semiconductor strips or isolation trenches and separated therefrom by a dielectric, wherein, for each of the at least one of the semiconductor strips that electrically connects the first and second interconnects, a corresponding one of the P-doped polysilicon strips is electrically connected to the first and second metal interconnects in parallel with the semiconductor strip.

12. The cooling structure of claim 9, further comprising one or more contacts electrically connecting the P-well of at least one of the semiconductor strips to the N-well.

13. The cooling structure of claim 9, further comprising a current source or voltage source configured to generate a DC current that flows from the first metal interconnect through the plurality of semiconductor strips to the second metal interconnect, the DC current flowing through the plurality of semiconductor strips in parallel.

14. The cooling structure of claim 1, wherein the plurality of semiconductor strips comprises two or more first semiconductor strips arranged alternatingly with two or more second semiconductor strips, each of the first semiconductor strips comprising an N-well and each of the second semiconductor strips comprising a P-well, the cooling structure further comprising:
a first metal terminal connected to one of the first semiconductor strips at a terminal point thereof, the terminal point being closer to the second end than to the first end of the strip; and
a second metal terminal connected to one of the second semiconductor strips at a terminal point thereof, the terminal point being closer to the second end than to the first end of the strip.

15. The cooling structure of claim 14, wherein each of the first semiconductor strips comprises an N+ doped layer disposed inside the N-well, and each of the second semiconductor strips comprises a P+ doped layer disposed inside the P-well.

16. The cooling structure of claim 14, further comprising a current source or voltage source configured to generate a DC current that flows from the first metal terminal through the plurality of semiconductor strips and through the first and second metal interconnects to the second metal terminal, wherein, within each pair of a first semiconductor strip and a second semiconductor strip, the DC current flows through the first and second semiconductor strips in series.

17. The cooling structure of claim 16, wherein the first and second metal interconnects are arranged such that the DC current flows through different pairs of a first semiconductor strip and a second semiconductor strip in parallel.

18. The cooling structure of claim 14, further comprising:
a plurality of N-doped polysilicon strips, each of the N-doped polysilicon strips being disposed on top of a corresponding one of the first semiconductor strips or isolation trenches and separated therefrom by a dielectric, wherein, for each of the first semiconductor strips that electrically connects the first and second interconnects, a corresponding one of the N-doped polysilicon strips is electrically connected to the first and second metal interconnects in parallel with the first semiconductor strip.
a plurality of P-doped polysilicon strips, each of the P-doped polysilicon strips being placed on top of a corresponding one of the second semiconductor strips or isolation trenches and separated therefrom by a dielectric, wherein, for each of the second semiconductor strips that electrically connects the first and second interconnects, a corresponding one of the P-doped polysilicon strips is electrically connected to the first and second metal interconnects in parallel with the second semiconductor strip.

19. A silicon-on-insulator (SOI) die comprising:
a semiconductor substrate;
a buried oxide (BOX) layer formed in the semiconductor substrate;
a P-well disposed on top of the buried oxide (BOX) layer;
an N-type metal-oxide-semiconductor (NMOS) transistor inside the P-well;
a plurality of semiconductor strips extending away from the P-well and separated from each other by isolation trenches, each of the semiconductor strips having first and second ends, the second end being farther than the first end from the P-well;
a first metal interconnect electrically connecting a first set of the semiconductor strips at respective first connection points thereof, the first connection point of each of the strips of the first set being closer to the first end than to the second end; and
a second metal interconnect electrically connecting a second set of the semiconductor strips at respective second connection points thereof, the second connection point of each of the strips of the second set being closer to the second end than to the first end, the second set having at least one of the semiconductor strips in common with the first set, the first and second metal interconnects being electrically connected to each other by the at least one of the semiconductor strips.

20. A radio frequency (RF) low noise amplifier comprising the SOI die of claim

21. A base station comprising the RF low noise amplifier of claim 20.

22. A method of cooling a silicon-on-insulator (SOI) metal-oxide-semiconductor field-effect transistor (MOSFET), the method comprising:
providing a plurality of semiconductor strips separated from each other by isolation trenches, each of the semiconductor strips extending away from a P-well disposed on top of a buried oxide (BOX) layer formed in a semiconductor substrate and having first and second ends, the second end being farther than the first end from the P-well;
applying a voltage to the plurality of semiconductor strips so as to generate, in at least one of the strips, a first area having a reduced temperature closer to the first end than to the second end of the strip and a second area having an increased temperature closer to the second end than to the first end of the strip, the first and second areas being generated by the Peltier effect.
